(19) United States
(12) Patent Application Publication
(10) Pub. No.: US 2006/0120489 A1
(43) Pub. Date: Jun. 8, 2006

(54) Adaptive frequency controller, a phase-locked loop including the same, and an adaptive frequency controlling method

(75) Inventor: Kun-Seok Lee, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/291,409

(22) Filed: Dec. 1, 2005

(30) Foreign Application Priority Data
Dec. 7, 2004 (KR) 10-2004-0102086

(51) Int. Cl. H04L 27/06; H03D 3/24

(52) U.S. Cl. 375/344; 375/376

(57) ABSTRACT

An adaptive frequency controller, a phase-locked loop including the same and an adaptive frequency controlling method are provided. In an adaptive frequency controller, a frequency detector compares a frequency of a first signal with a frequency of a second signal. A state machine adjusts a code position based on a lo result of the comparison of the frequencies of the first and second signals. An initial code generator receives a locking frequency, determines an estimation code, and sets a code range to be searched. An AFC code generator generates a code value from the determined estimation code based on the code position of the state machine.

### CROSS-REFERENCE TO RELATED APPLICATION

This application claims priority to Korean Patent Application No. 2004-102086, filed on Dec. 7, 2004, the disclosure of which is incorporated by reference herein in its entirety.

### BACKGROUND OF THE INVENTION

1. Technical Field

The present invention relates to an adaptive frequency controller, a phase-locked loop including the same, and an adaptive frequency controlling method.

2. Discussion of the Related Art

Generally, a radio communication system uses a radio frequency (RF) transceiver for transmitting or receiving RF signals. The RF transceiver uses a phase-locked loop (PLL) to lock a wanted frequency. In other words, the PLL is used to maintain a generated signal in a fixed relationship to a reference signal.

As the use of wide frequency bands for transmitting or receiving RF signals increases, a gain of a voltage-controlled oscillator (VCO) used by the PLL to create wide frequency bands also increases. However, as the gain of the VCO increases, a phase noise or jitter of the PLL increases. Therefore, it is difficult to create the wide frequency bands by using a low power supply voltage of, for example, 1.8 V or less.

One method for reducing the phase noise while creating a wide frequency band is to apply an adaptive frequency controller (AFC) to a PLL.

FIG. 1 is a graph of a VCO transfer curve used by an AFC for searching for an AFC code.

Referring to FIG. 1, an overall frequency domain cannot be calculated by using a single VCO transfer curve. Thus, to use wide frequency bands, a plurality of VCO transfer curves is created by controlling a capacitance (C) of a switch capacitor and an inductance (L) in the VCO, and by controlling a voltage of a varactor also in the VCO.

As illustrated in FIG. 1, a plurality of VCO transfer curves are created which include a VCO transfer curve having a VCO gain of 5.2 MHz/Volt and a frequency spacing of 1.2 MHz, a VCO transfer curve having a VCO gain of 9.2 MHz/Volt and a frequency spacing of 2.2 MHz, and a VCO transfer curve having a VCO gain of 17.5 MHz/Volt and a frequency spacing of 4.2 MHz. Using the VCO transfer curves, the AFC then finds an optimal curve associated with a VCO frequency range by performing a variety of search techniques.

FIG. 2 is a diagram of a conventional sequential code search used by the AFC.

Referring to FIG. 2, the conventional sequential code search finds an optimal code associated with the optimal curve while shifting a code from a lower code to an upper code (or from an upper code to a lower code) one by one in sequence. The code is shifted in one direction and the relationships between the codes are checked in sequence. Accordingly, the sequential code search can be easily implemented in the AFC. However, when N bits are checked (where N is a positive integer equal to or greater than 1), an AFC time is (2^{N}−1)×(1 comparison time). Therefore, when the value of N is great, the total locking time is lengthy due to the application of the sequential code search.

FIG. 3 is a diagram of a conventional binary code search used by the AFC.

Referring to FIG. 3, the conventional binary code search finds the optimal code while shifting a code from a middle code to a center of an upper or lower code. Accordingly, the implementation of the binary code search in the AFC is complicated as compared with the sequential code search. However, when N bits are checked, an AFC time is (N−1)×(1 comparison time). Therefore, a total locking time can be reduced as compared with the sequential code search. For example, when 5 bits are checked, an AFC time is four times that of a comparison time; however, in the sequential code search, an AFC time is thirty-one times that of a comparison time.

As the demand for applications employing wide frequency bands increases, the number of bits checked by the AFC also increases. Thus, the AFC locking time is becoming an important design constraint for reducing overall locking time in a PLL. Therefore, because reduced locking times are desired in next-generation transceivers, there is a need for a high-speed AFC that can reduce the AFC locking time.

### SUMMARY OF THE INVENTION

Embodiments of the present invention provide an AFC and an adaptive frequency controlling method that can reduce an AFC locking time and a PLL including the AFC that can reduce a phase locking time.

In an exemplary embodiment, an AFC includes a frequency detector, a state machine, an initial code generator, and an AFC code generator. The frequency detector compares a frequency of a first signal with a frequency of a second signal. The state machine adjusts a code position based on a result of the comparison of the frequencies of the first and second signals. The initial code generator determines an estimation code, and sets a code range to be searched based on a locking frequency. The AFC code generator generates a code value from the determined estimation code based on the code position of the state machine.

The AFC code generator may include an adder. The first signal may be a reference clock signal, and the second signal may be a signal generated by dividing a frequency of an output signal of the VCO. The frequency detector may include two counters and one comparator.

The AFC may further include a counting time control logic configured to control a counting interval of the counters so that the counting interval of the counters is shorter at a high code corresponding to a high frequency than at a low code corresponding to a low frequency. The initial code generator may include a code range storing unit configured to store frequency information corresponding to an uppermost code and frequency information corresponding to a lowermost code. In addition, the AFC code generator may increase or decrease the estimated code by the code position to generate the code value. The code position may be generated from the state machine.

In another exemplary embodiment, an adaptive frequency controlling method includes: receiving a first signal and a second signal; comparing a frequency of the first signal with a frequency of the second signal; adjusting a code position based on a result of the comparison of the frequencies of the first and second signals; determining an estimation code to set a code range to be searched based on a locking frequency; and generating a first code value from the determined estimation code based on the adjusted code position.

The adaptive frequency controlling method may further include: stopping a search of the code range when a frequency difference between the first signal and the second signal is within a preset range; and determining a final code value as a code value that was generated before the search is stopped.

In still another exemplary embodiment, a PLL includes a phase-frequency comparator, a charge pump, a low pass filter, an AFC, and a VCO. The phase-frequency comparator compares a frequency and a phase of a reference clock signal with a frequency and a phase of a signal produced by dividing a frequency of an output signal of a voltage-controlled oscillator (VCO), and generates an up signal and a down signal. The charge pump generates a first control signal corresponding to a pulse width of the up signal and the down signal. The low pass filter filters the first control signal to generate a second control signal corresponding to a change of the first control signal. The AFC receives the reference clock signal and the divided signal to generate an adaptive frequency control signal. The VCO controls a 10 frequency of an oscillation signal in response to the second control signal within an oscillation frequency range corresponding to the adaptive frequency control signal.

The AFC includes a frequency detector, a state machine, an initial code generator, and an AFC code generator. The frequency detector compares the frequency of the reference clock signal with the frequency of the divided signal. The state machine adjusts a code position based on a result of the comparison of the frequencies of the reference clock signal and the divided signal. The initial code generator determines an estimation code, and sets a code range to be searched based on a locking frequency. The AFC code generator generates a code value from the determined estimation code based on the code position of the state machine. In addition, the PLL may further include a reference clock signal divider configured to divide a frequency of an external clock to generate the reference clock signal.

### BRIEF DESCRIPTION OF THE DRAWINGS

The above and other features of the present invention will become more apparent by describing in detail exemplary embodiments thereof with reference to the accompanying drawings, in which:

FIG. 1 is a graph of a VCO transfer curve;

FIG. 2 is a diagram of a conventional sequential code search;

FIG. 3 is a diagram of a conventional binary code search;

FIG. 4 is a block diagram of a PLL according to an exemplary embodiment of the present invention;

FIG. 5 is a block diagram of an AFC illustrated in FIG. 4;

FIG. 6 is a graph illustrating a reference clock signal and a feedback signal for explaining an exemplary frequency comparison in a frequency detector of FIG. 5;

FIG. 7 is a state diagram of a state machine illustrated in FIG. 5;

FIG. 8 is a diagram illustrating a code estimation and a binary search according to an exemplary embodiment of the present invention;

FIG. 9 is a diagram for explaining an operation of a counting time control logic of the AFC illustrated in FIG. 5; and

FIG. 10 is a flowchart illustrating a method of finding a VCO transfer curve by using the AFC illustrated in FIG. 5.

### DESCRIPTION OF EXEMPLARY EMBODIMENTS

Hereinafter, exemplary embodiments of the present invention will be described in detail with reference to the accompanying drawings. However, specific structural and functional details disclosed herein are merely presented for purposes of describing the exemplary embodiments of the present invention.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the is terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

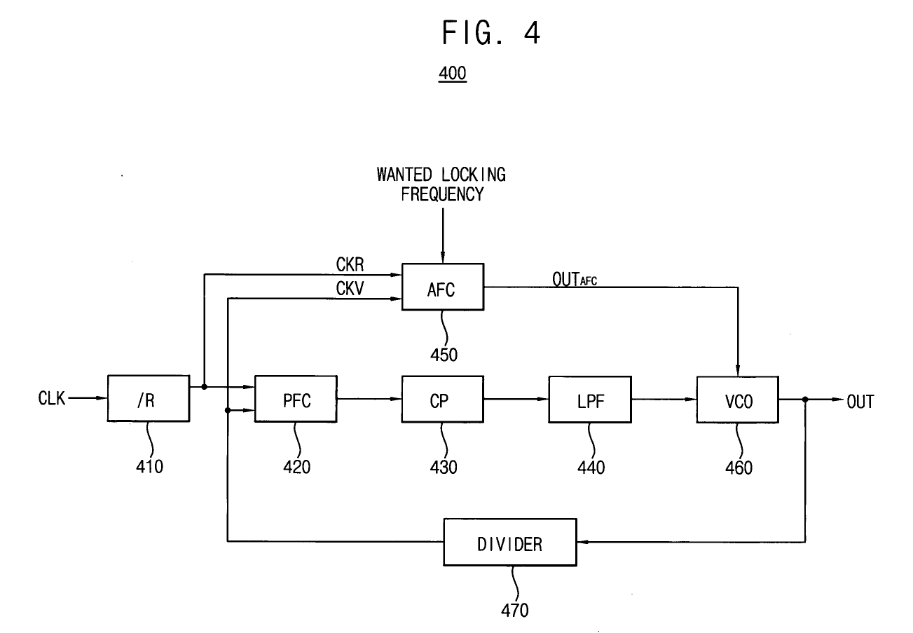

FIG. 4 is a block diagram of a phase locked loop (PLL) 400 according to an exemplary embodiment of the present invention.

Referring to FIG. 4, the PLL 400 includes a reference clock signal divider (/R) 410, a phase-frequency comparator (PFC) 420, a charge pump (CP) 430, a low pass filter (LPF) 440, an adaptive frequency controller (AFC) 450, a voltage-controlled oscillator (VCO) 460, and a divider 470.

The reference clock signal divider (/R) 410 receives an external clock signal CLK and divides the external clock signal CLK to generate a reference clock signal CKR. When a frequency of the external clock signal CLK is low, the reference clock signal divider (/R) 410 may not be used.

The phase-frequency comparator (PFC) 420 receives the reference clock signal CKR and a feedback signal CKV, which is generated from the divider 470 by dividing a frequency of an output signal OUT of the VCO 460. Then, the phase-frequency comparator (PFC) 420 compares a frequency and a phase of the reference clock signal CKR with those of the feedback signal CKV, and generates an up signal and a down signal, which are pulse sequences corresponding to the frequency and phase difference between the reference clock signal CKR and the feedback signal CKV. Each of the pulse sequences has a pulse width that is substantially proportional to the frequency and phase difference between the reference clock CKR and the feedback signal CKV.

The charge pump (CP) 430 generates a signal based on the up signal and the down signal. Specifically, the charge pump (CP) 430 generates a current that is substantially proportional to pulse widths of the up signal and the down signal. Since the charge pump (CP) 430 is well known to one of ordinary skill in the art, a detailed description thereof will be omitted.

The low pass filter (LPF) (or, for example, a loop filter) 440 filters the output signal of the charge pump (CP) 430 and passes only low frequency components to the VCO 460. In addition, the low pass filter (LPF) 440 varies a control voltage by changing an amount of electric charges charged in a capacitor according to a change of a current outputted from the charge pump (CP) 430, and applies the control voltage to the VCO 460. Since the low pass filter (LPF) 440 is a general low pass filter in which a resistor (not shown) and a capacitor (not shown) are connected together, a detailed description thereof will be omitted.

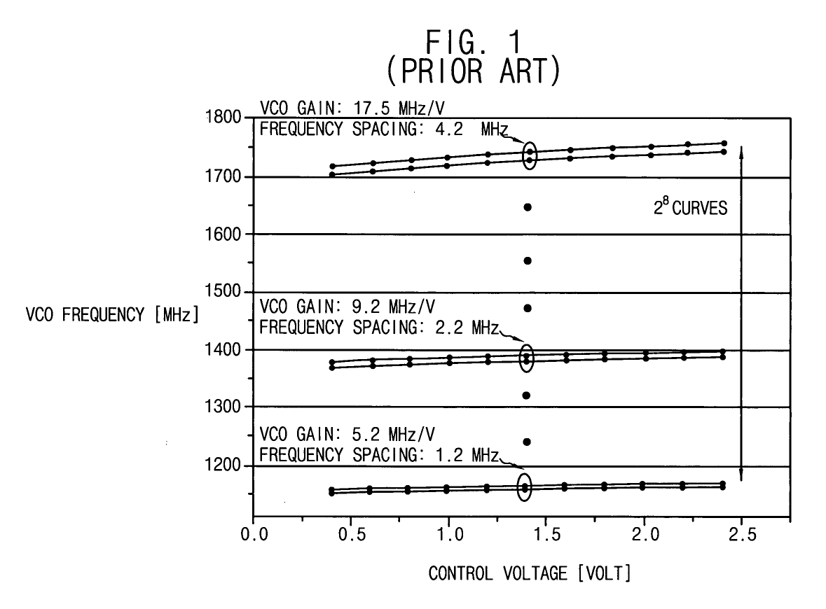

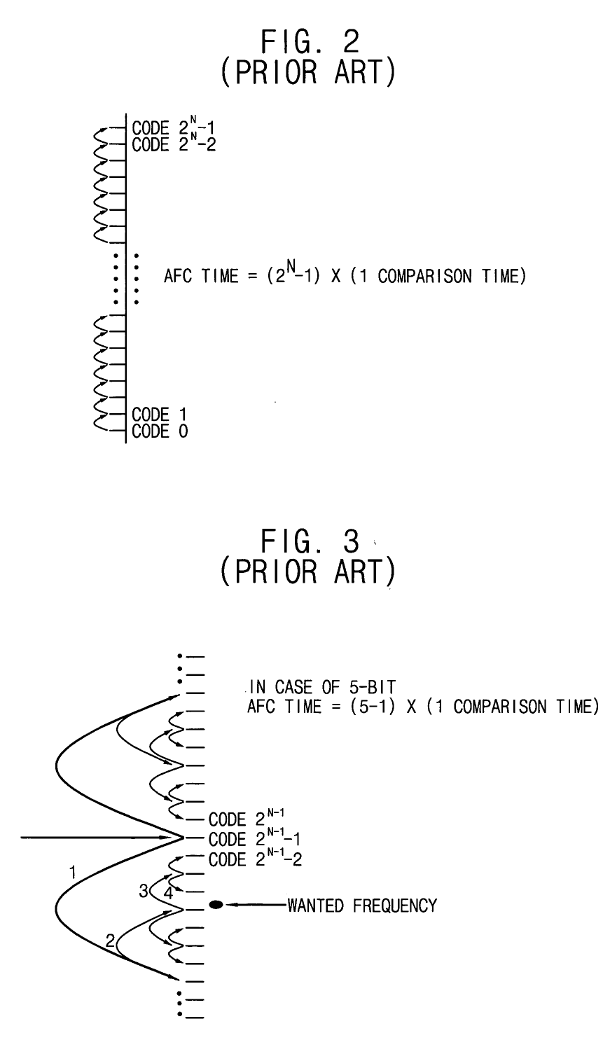

As further shown in FIG. 4, the AFC 450 receives the reference clock signal CKR and the feedback signal CKV to generate an adaptive frequency control signal OUT_{AFC}. The VCO 460 then selects one VCO transfer curve among a plurality of VCO transfer curves as illustrated, for example, in FIG. 1, according to the adaptive frequency control signal OUT_{AFC}, and finely controls the frequency of the oscillation signal within the VCO frequency range of the selected VCO transfer curve in response to the control voltage outputted from the low pass filter (LPF) 440.

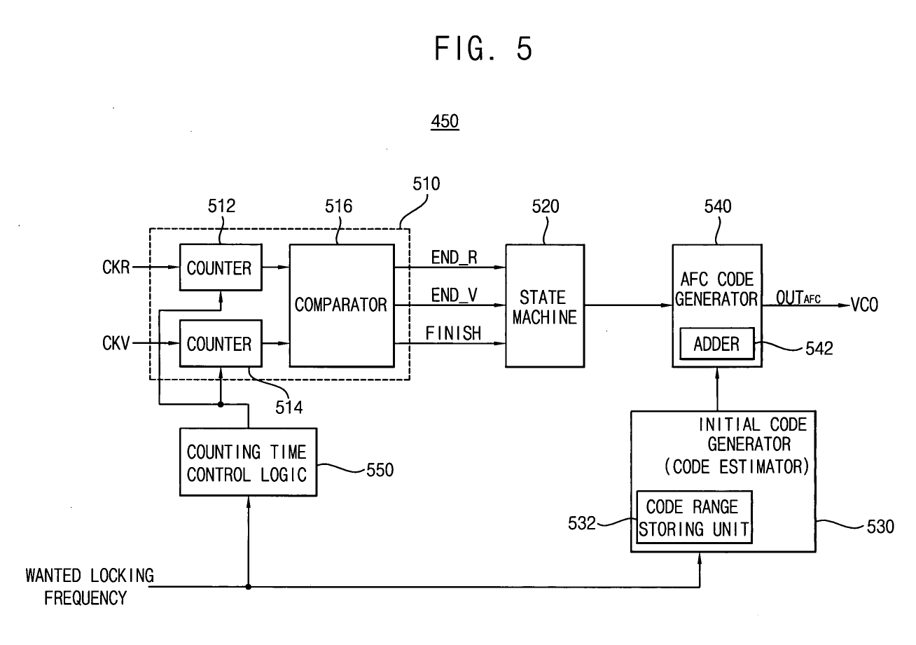

FIG. 5 is a block diagram of the AFC 450 illustrated in FIG. 4.

Referring to FIG. 5, the AFC 450 includes a frequency detector 510, a state machine 520, an initial code generator (code estimator) 530, and an AFC code generator 540.

The frequency detector 510 compares a frequency of the reference clock signal CKR and a frequency of the feedback signal CKV.

The frequency detector 510 includes a first counter 512 for counting a frequency of the reference clock signal CKR, a second counter 514 for counting a frequency of the feedback signal CKV, and a comparator 516 for comparing the frequency of the reference clock signal CKR and the frequency of the feedback signal CKV.

When the frequency of the reference clock signal CKR is higher than that of the feedback signal CKV, the frequency detector 510 generates a signal END_R. When the frequency of the feedback signal CKV is higher than that of the reference clock signal CKR, the frequency detector 510 generates a signal END_V. In addition, when the frequency of the reference clock signal CKR is almost equal to that of the feedback signal CKV, the frequency detector 510 generates a signal FINISH. The frequency detector 510 then transmits one of the signals END_R, END_V or FINISH to the state machine 520.

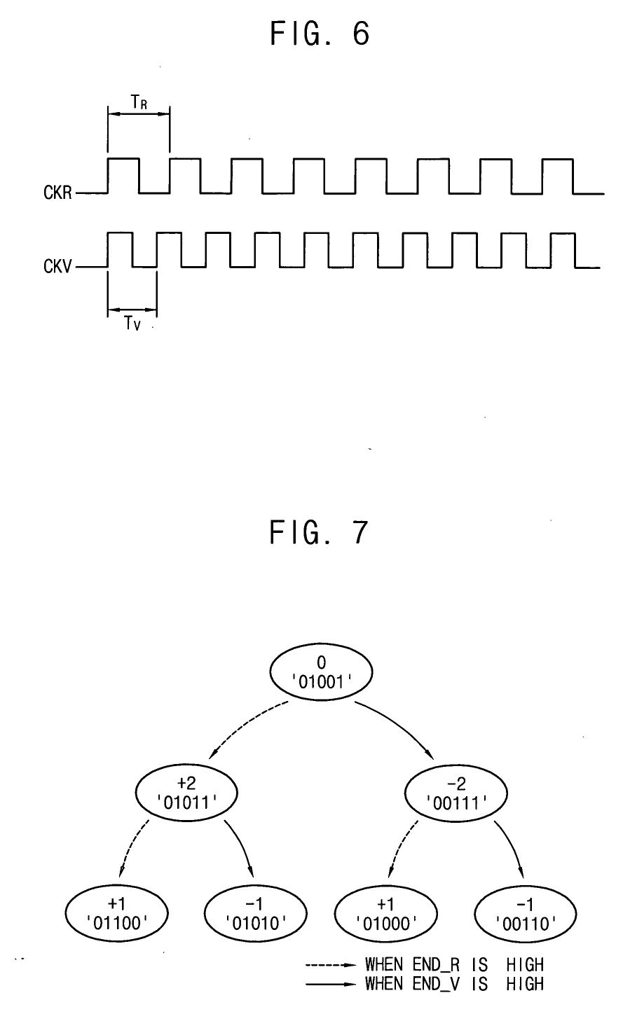

FIG. 6 is a graph illustrating the reference clock signal CKR and the feedback signal CKV for explaining an exemplary frequency comparison in the frequency detector 510 of FIG. 5.

Referring to FIG. 6, the reference clock signal CKR and the feedback signal CKV are inputted to the first counter 512 and the second counter 514, respectively. When T_{R} represents a time period corresponding to 1 cycle of the reference clock signal CKR, T_{V} represents a time period corresponding to 1 cycle of the feedback signal CKV, which is shorter than T_{R}, and M represents a count value of the frequencies of the reference clock signal CKR and the feedback signal CKV, Equation 1 below is satisfied.
M·T_{R}−M·T_{V}≧2·T_{R} [Equation 1]

In Equation 1, ‘2’ represents a preset value that is used to calculate a minimum frequency difference that can be compared by the frequency detector 510 when a synchronization mismatch between the reference clock signal CKR and the feedback signal CKV is a maximum of 1 period, and a period difference between CKR and CKV is almost 1 period.

Equations 2 through 4 are provided below to illustrate the derivation of the minimum comparable frequency difference Δfₘᵢₙ shown in Equation 5.
T_{R}−T_{V}≧(2/M)T_{R} [Equation 2]
1−(T_{V}/T_{R})≧2/M [Equation 3]
1−(f_{R}If_{V})≧2/M [Equation 4]
Δfₘᵢₙ≧(2/M)f_{V}≈(2/M)f_{R} [Equation 5]

Accordingly, when applying, for example, a count value M of 128 and a reference clock signal CKR of 50 MHz to Equation 5, the comparable minimum frequency difference Δfₘᵢₙ becomes 718 kHz. In other words, when the minimum frequency difference Δfₘᵢₙ between the reference clock signal and CKR and the feedback signal CKV is less than 718 kHz, the signal FINISH is generated and sent to the state machine 520.

Referring back to FIG. 5, the state machine 520 receives one of the signals END_R, END_V or FINISH outputted from the frequency detector 510 after comparing the frequency of the reference clock signal CKR with the frequency of the feedback signal CKV, and determines a relative code position according to the received signals END_R, END_V or FINISH.

FIG. 7 is a state diagram of the state machine 520 of the AFC 450.

The exemplary state machine 520 illustrated in FIG. 7 is a 3-bit state machine. As shown in FIG. 7, an initial code value (e.g., an estimation code or a code center value) of the AFC 450 is ‘01001’. The initial code value is used to find the relative code position.

For example, when the frequency detector 510 outputs the signal END_R, when the frequency of the reference clock signal CKR is higher than that of the feedback signal CKV, the code value increases by 2 (+2). Thus, the code value becomes ‘01011’. When the frequency detector 510 outputs the signal END_V, when the frequency of the reference clock signal CKR is lower than that of the feedback signal CKV, the code value decreases by 2 (−2). Thus, the code value becomes ‘00111’.

In the state in which the code value is ‘00111’, the outputs of the frequency detector 510 are compared each other. For example, when the output of the frequency detector 510 is END_R, the code value increases by 1 (+1) and thus becomes ‘01000’. In addition, when the output of the frequency detector 510 is END_V, the code value decreases by 1 (−1) and thus becomes ‘00110’. In other words, all bits are simultaneously changed until the operation of the AFC 450 is finished.

Although the 3-bit state machine has been described with reference to FIG. 7, a 4-bit state machine and so forth can be used in accordance with an exemplary embodiment of the present invention. For example, when using the 4-bit state machine to perform the comparing operation, the code value increases or decreases by 4, then increases or decreases by 2, and then increases or decreases by 1.

Referring back to FIG. 5, the initial code generator (code estimator) 530 receives a frequency that is desired to be locked, hereinafter referred to as an external wanted locking frequency or the wanted locking frequency, determines an estimation code (or code center value), and sets a code range to be searched. The code range corresponds to the frequency range, and the code center value corresponds to the center frequency within the frequency range.

According to an exemplary embodiment of the present invention, the initial code generator 530 can be implemented with hardware or software. In addition, after a chip embodying the AFC 450 is fabricated, the initial code generator 530 may include a code range storing unit 532 that stores frequency information corresponding to an uppermost code and a lowermost code.

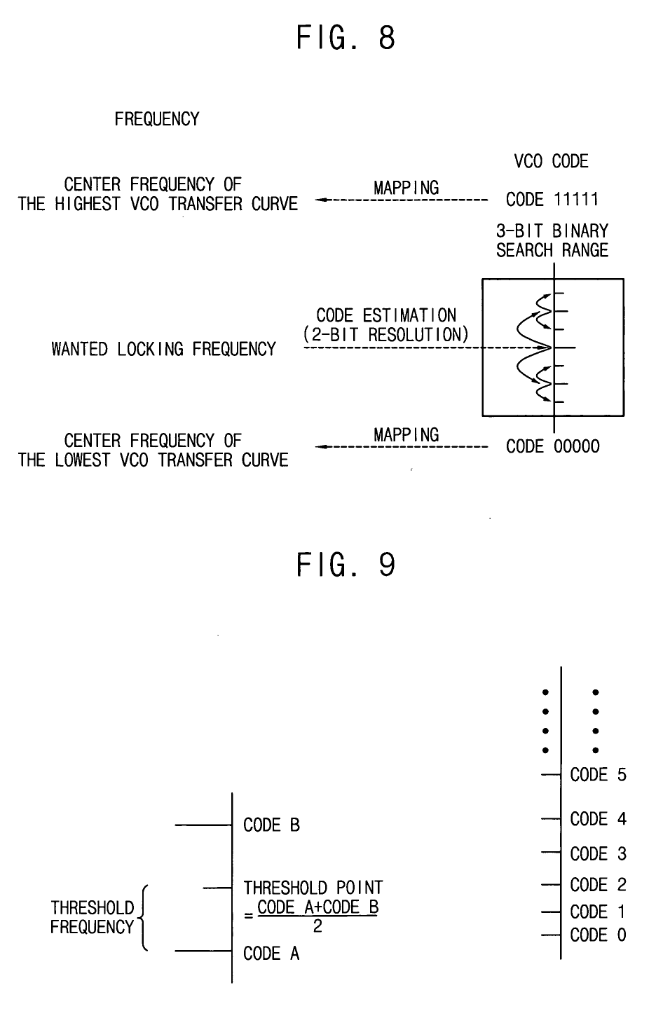

FIG. 8 is a diagram illustrating a code estimation and a binary search according to an exemplary embodiment of the present invention.

Referring to FIG. 8, the code range storing unit 532 stores the center frequency of the lowest VCO transfer curve when the code value is ‘00000’, and stores the center frequency of the highest VCO transfer curve when the code value is ‘11111’.

Referring to FIGS. 5 and 8, the AFC code generator 540 generates the adaptive frequency control signal OUT_{AFC} (e.g., the code value corresponding to the wanted locking frequency) from the estimation code, determined by the initial code generator 530, by using the relative code position received from the state machine 520. The generated code value is inputted to the VCO 460.

The VCO 460 receives the code value corresponding to the wanted locking frequency, for example, through switches with a binary structure configured with capacitors, and generates the oscillation frequency corresponding to the code value.

As further shown in FIG. 5, the AFC code generator 540 includes an adder 542.

The code value inputted to the VCO 460 is changed into the output signal OUT at the VCO 460. Then, the output signal OUT is inputted as the feedback signal CKV to the frequency detector 510 of the AFC 450, and is compared with the reference clock signal CKR.

When the frequency of the feedback signal CKV is almost equal to that of the reference clock signal CKR, the frequency detector 510 generates the signal FINISH and a final code value (e.g., the VCO transfer curve) is determined. In addition, when the frequency of the feedback signal CKV is different from that of the reference clock signal CKR, the state machine 520 controls and changes the relative position of the code in a way illustrated in FIG. 7. The AFC code generator 540 then finds a new code value through the binary search.

As further shown in FIG. 5, the AFC 450 further includes counting time control logic 550. According to an exemplary embodiment of the present invention, the counting time control logic 550 can be implemented with hardware or software.

FIG. 9 is a diagram for explaining an operation of the counting time control logic 550 of the AFC 450.

Referring to FIG. 9, a frequency spacing is narrow at a low code and is wide at a high code. Accordingly, the counting time control logic 550 controls the counting time of the counters 512 and 514 so that the counting time of the counters 512 and 514 is shorter at the high code than at the low code. Thus, allowing for precise control of the frequency associated with the VCO transfer curve.

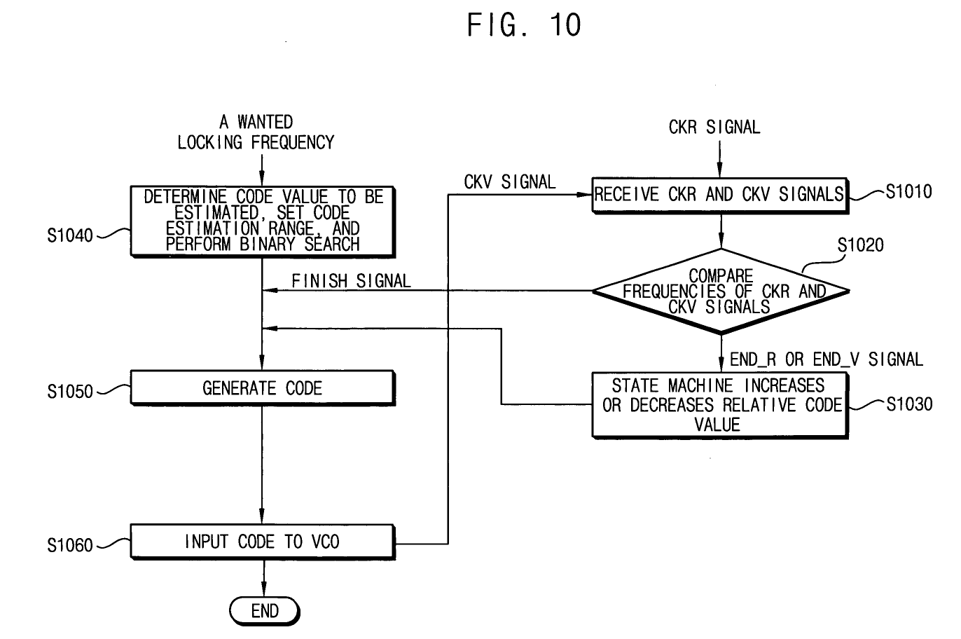

FIG. 10 is a flowchart illustrating a method of finding the VCO transfer curve by using the AFC 450.

The process of finding the VCO transfer curve will be described below with reference to FIGS. 4, 5 and 10.

In step S1010, the frequency detector 510 receives the reference clock signal CKR and the feedback signal CKV. In step S1020, the comparator 516 of the frequency detector 510 compares the frequency of the reference clock signal CKR with the frequency of the feedback signal CKV. When the frequency of the reference clock signal CKR is higher than that of the feedback signal CKV, the frequency detector 510 generates the signal END_R. When the frequency of the feedback signal CKV is higher than that of the reference clock signal CKR, the frequency detector 510 generates the signal END_V. In addition, when the frequency of the reference clock signal CKR is almost equal to that of the feedback signal CKV, the frequency detector 510 generates the signal FINISH. In step S1030, the state machine 520 increases or decreases the code position based on the signal END_R, END_V or FINISH.

In step S1040, the initial code generator 530 receives the external wanted locking frequency, determines the estimation code (or the code center value), sets the code range to be searched, and performs the binary search. In step S1050, the AFC code generator 540 generates the code by using the searched code.

In step S1060, the generated code is transmitted to the VCO 460, and the signal produced by dividing the frequency of the output signal of the VCO 460 is again transmitted as the feedback signal CKV to the frequency detector 510.

Thereafter, the process returns to step S1010. At this point, the frequency detector 510 receives the reference clock signal CKR and the feedback signal CKV (S1010), and the comparator 516 of the frequency detector 510 compares the frequency of the reference clock signal CKR with the frequency of the feedback signal CKV (S1020). When the two frequencies are similar to each other within a preset range, the frequency detector 510 generates the signal FINISH. When the signal FINISH is generated, the code value just before the signal FINISH is generated is decided as the final code value (e.g., the VCO transfer curve). In this manner, the operation of the AFC 450 is completed.

According to an exemplary embodiment of the present invention, the AFC 450 includes the initial code generator 530 configured to receive the external wanted locking frequency, determine the estimation code (or center code value) and set the code range to be searched. Therefore, the code search can be rapidly performed and thus frequency locking can be achieved effectively and quickly.

In addition, the counting time control logic 550 of the AFC 450 controls the counting time to be shorter at the high code than at the low code. Therefore, the AFC 450 can be precisely controlled.

According to another exemplary embodiment of the present invention, the PLL 400 includes the AFC 450 to create wide frequency bands for radio communication. For example, the AFC 450 first determines a frequency range wanted to be locked, and then determines a frequency wanted to be finally locked within the frequency range.

While the present invention has been particularly shown and described with reference to exemplary embodiments thereof, it will be apparent to those skilled in the art that various changes and modifications may be made therein without departing from the spirit and scope of the invention as defined in the following claims.

What is claimed is:

1. An adaptive frequency controller (AFC), comprising:
a frequency detector configured to compare a frequency of a first signal with a frequency of a second signal;
a state machine configured to adjust a code position based on a result of the comparison between the frequencies of the first and second signals;
an initial code generator configured to receive a locking frequency, determine an estimation code, and set a code range to be searched; and
an AFC code generator configured to generate a code value from the determined estimation code based on the code position of the state machine.

2. The AFC of claim 1, wherein the code value generated from the AFC code generator is inputted to a voltage-controlled oscillator (VCO) of a phase-locked is loop (PLL).

3. The AFC of claim 2, wherein the AFC code generator includes an adder.

4. The AFC of claim 2, wherein the first signal is a reference clock signal, and the second signal is a signal produced by dividing a frequency of an output signal of the VCO.

5. The AFC of claim 4, wherein the frequency detector includes two counters and one comparator.

6. The AFC of claim 5, wherein a first counter of the two counters receives the frequency of the first signal, and a second counter of the two counters receives the frequency of the second signal.

7. The AFC of claim 5, further comprising:
a counting time control logic configured to control a counting time of the counters so that the counting time of the counters is shorter at a high code corresponding to a high frequency than at a low code corresponding to a low frequency.

8. The AFC of claim 1, wherein the initial code generator includes a code range storing unit configured to store frequency information corresponding to an uppermost code and frequency information corresponding to a lowermost code.

9. The AFC of claim 1, wherein the AFC code generator increases or decreases the estimation code by the code position to generate the code value.

10. An adaptive frequency controlling method, comprising:
receiving a first signal and a second signal;
comparing a frequency of the first signal with a frequency of the second signal;
adjusting a code position based on a result of the comparison between the frequencies of the first and second signals;
determining an estimation code to set a code range to be searched based on a locking frequency; and
generating a first code value from the determined estimation code based on the adjusted code position.

11. The adaptive frequency controlling method of claim 10, further comprising:
stopping a search of the code range when a frequency difference between the first signal and the second signal is within a preset range; and
determining a final code value as a code value that was generated before the search is stopped.

12. The adaptive frequency controlling method of claim 11, wherein the first code value is inputted to a voltage-controlled oscillator (VCO) of a phase-locked loop (PLL).

13. The adaptive frequency controlling method of claim 12, wherein the first code value is generated by adding the determined estimation code to the adjusted code position.

14. The adaptive frequency controlling method of claim 12, wherein the first signal corresponds to a reference clock signal, and the second signal corresponds to a signal generated by dividing a frequency of an output signal of the VCO.

15. The adaptive frequency controlling method of claim 11, wherein the frequencies of the first and second signals are compared by performing clock counting.

16. The adaptive frequency controlling method of claim 15, wherein the clock counting is performed to control a counting time so that the counting time is shorter at a high code corresponding to a high frequency than at a low code corresponding to a low frequency.

17. The adaptive frequency controlling method of claim 11, wherein the code range is determined based on frequency information corresponding to an uppermost code and frequency information corresponding to a lowermost code.

18. The adaptive frequency controlling method of claim 11, wherein the code position is determined by performing a binary search.

19. A phase-locked loop (PLL), comprising:
a phase-frequency comparator configured to compare a frequency and a phase of a reference clock signal with a frequency and a phase of a signal generated by dividing a frequency of an output signal of a voltage-controlled oscillator (VCO), and to generate an up signal and a down signal;
a charge pump configured to generate a first control signal corresponding to pulse widths of the up signal and the down signal;
a low pass filter configured to filter the first control signal to generate a second control signal corresponding to a change of the first control signal;
an adaptive frequency controller (AFC) configured to generate an adaptive frequency control signal based on the reference clock signal and the divided signal; and
the VCO configured to control a frequency of an oscillation signal in response to the second control signal within an oscillation frequency range corresponding to the adaptive frequency control signal,
wherein the AFC includes:
a frequency detector configured to compare the frequency of the reference clock signal with the frequency of the divided signal,
a state machine configured to adjust a code position based on a result of the comparison of the frequencies of the reference clock signal and the divided signal;
an initial code generator configured to determine an estimation code and set a code range to be searched based on a locking frequency; and
an AFC code generator configured to generate a code value from the determined estimation code based on the code position of the state machine.

20. The PLL of claim 19, further comprising:
a reference clock signal divider configured to divide a frequency of an external clock to generate the reference clock signal.

21. The PLL of claim 19, wherein the frequency detector includes two counters and one comparator.

22. The PLL of claim 21, wherein the AFC further includes a counting time control logic configured to control a counting time of the counters so that the counting time of the counters is shorter at a high code corresponding to a high frequency than at a low code corresponding to a low frequency.

23. The PLL of claim 19, wherein the initial code generator includes a code range storing unit configured to store frequency information corresponding to an uppermost code and frequency information corresponding to a lowermost code.

24. The PLL of claim 19, wherein the AFC code generator increases or decreases the estimated code by the code position to generate the code value.
